(19) United States
(12) Patent Application Publication
(10) Pub. No.: US 2014/0353028 A1
(43) Pub. Date: Dec. 4, 2014

(54) ALTERNATIVE MANUFACTURING PROCESSES FOR ALUMINUM ENCLOSURES

(71) Applicant: Apple Inc., Cupertino, CA (US)

(72) Inventor: Wey-Jiun Lin, Los Altos Hills, CA (US)

(73) Assignee: Apple Inc.

(21) Appl. No.: 13/904,934

(22) Filed: May 29, 2013

(51) Int. Cl. H05K 5/02; C25D 5/02; B21D 51/16; C22F 1/04; B21C 23/00; B21B 1/00

(52) U.S. Cl. CPC H05K 5/0217; H05K 5/0247; B21C 23/00; B21B 1/00; B21D 51/16; C22F 1/04; C25D 5/02
USPC 174/535; 264/261; 72/253.1; 72/199; 72/379.4; 148/695; 205/121; 72/39

(57) ABSTRACT

Methods for forming aluminum enclosures for consumer products are described. Included are methods for forming features, such as brackets or supports for supporting one or more internal components of the consumer product. In some embodiments, methods involve shaping integral features into the aluminum enclosures. In some embodiments, methods involve molding resinous or plastic features onto the aluminum enclosures. Some methods involve one or more of an extrusion, rolling, stamping, bending, forging and other shaping techniques. Some methods involve a metal softening technique such as an annealing process. Some methods involve post-shaping treatments including one or more of an impurity removal process, hardening process and surface finishing process. Some embodiments involve forming nano-pores in aluminum enclosures and inserts to enhance bonding of plastic features to the aluminum enclosures and inserts.

### FIELD OF THE DESCRIBED EMBODIMENTS

The described embodiments relate generally to aluminum enclosures for consumer products and methods for forming the same. Methods include alternative manufacturing processes for producing cosmetically appealing aluminum enclosures.

### BACKGROUND

Enclosures for consumer products, such as consumer electronic products, are often made of stainless steel due to the durability and corrosion resistance of stainless steel. Typically, the enclosures are manufactured by stamp pressing stainless steel into a shape of the enclosure and then welding on metal features, such as interior brackets to support components within the enclosure. It can be difficult, however, to produce a lasting colored finish on stainless steel. Known processes, such as electrochemical or physical vapor deposition (PVD) techniques can be used to give stainless steel a colored finish. However, these colored finishes are usually susceptible to scratching and marring.

Aluminum is not only durable and corrosion resistant but it can also be anodized to provide a lasting finish having any of a number of colors. However, aluminum has different physical properties than stainless steel. For example, aluminum is generally not as stiff as stainless steel. Therefore, processes for producing stainless steel enclosures are not necessarily directly transferable to producing aluminum enclosures. For example, it can be difficult to weld features such as brackets onto enclosures made of aluminum.

### SUMMARY

This paper describes various embodiments that relate to manufacturing processes for producing aluminum consumer products. Methods for forming and treating cosmetically appealing aluminum enclosures are described.

According to one embodiment described herein, a method for forming an aluminum enclosure for an electronic device is described. The method includes performing a shaping operation on the aluminum enclosure. The method also includes comparing a current shape of the aluminum enclosure to a final shape of the aluminum enclosure. The method additionally includes performing a conditioning operation on the aluminum enclosure if, based on the comparison, the current shape is not the final shape. The method can further include repeating the shaping, comparing and conditioning operations until the current shape is the final shape. The method also includes performing a post-shaping operation on the aluminum enclosure.

According to another embodiment, an additional method for forming an aluminum enclosure for an electronic device is described. The method involves shaping the aluminum enclosure into a first shape having a back portion integrally formed with side walls. The back portion can have an interior surface and an exterior surface. The back portion and the side walls can create a cavity having a shape and size suitable for housing at least one internal component. The method also includes conditioning the aluminum enclosure such that at least a portion of the aluminum enclosure is softened to prevent cracking during a subsequent shaping process. The method additionally includes shaping the aluminum enclosure into a second shape having at least one integral feature integrally formed in the back portion and protruding a distance from the interior surface. The at least one integral feature can be configured to support at least one fastener used to fasten the at least one internal component within the cavity of the aluminum enclosure.

According to an additional embodiment, an aluminum enclosure for an electronic device is described. The aluminum enclosure includes an interior surface having a first group of nano-pores. The aluminum enclosure also includes at least one bracket secured to the interior surface and configured to support at least one component to the aluminum enclosure. The bracket includes an aluminum insert and a resinous member. The aluminum insert has an external surface having a second group of nano-pores. The resinous member has a first securing portion and a second securing portion. The first securing portion is molded within at least a portion of the interior surface having the first group of nano-pores. The second securing portion is molded within at least a portion of the external surface having the second group of nano-pores.

According to a further embodiment, a method of forming a bracket for an aluminum enclosure is described. The method includes creating a first group of nano-pores in an interior surface of an aluminum enclosure. The method also includes creating a second group of nano-pores in an exterior surface of an aluminum insert. The method additionally includes forming a supportive bracket on the interior surface of the aluminum enclosure. Forming the supportive bracket includes molding a first securing portion of a resinous member within at least a portion of the interior surface comprising the first group of nano-pores. Forming the supportive bracket also includes molding a second securing portion of the resinous member within at least a portion of the external surface comprising the second group of nano-pores.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 shows a flowchart for a process of forming an aluminum enclosure with integrally formed features in accordance with described embodiments.

FIG. 2 shows a flowchart for a microstructure treatment process in accordance with described embodiments.

FIG. 3 shows a flowchart for a surface finishing process in accordance with described embodiments.

FIGS. 4A-4C illustrate internal views of an aluminum enclosure having integrally formed features at various stages of formation in accordance with described embodiments.

FIG. 5 shows a flowchart for a process of forming plastic features on an aluminum substrate in accordance with described embodiments.

FIG. 6 illustrates a cross-section view of a portion of an aluminum enclosure with plastic features formed using the process described in the flowchart of FIG. 5.

FIG. 7 illustrates an internal view of an aluminum enclosure assembly with plastic features formed using the process described in the flowchart of FIG. 5.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting. That is, other embodiments may be used, and changes may be made without departing from the spirit and scope of the described embodiments.

Described herein are improved methods for forming aluminum enclosures or housings, such as enclosures for consumer products. As used herein, aluminum can refer to any suitable aluminum containing material, including pure aluminum and aluminum alloys. If an aluminum alloy is used, the type of alloy can be chosen, in part, on desired physical and cosmetic properties. In some embodiments, 5000 and 6000 series aluminum alloys are used. Methods described are well suited for manufacture of enclosures for electronic devices including computers, smart phones and media players, such as those designed and sold by Apple Inc. headquartered in Cupertino, Calif.

Often, the enclosures for electronic devices have internal features, such as brackets or supports, which can be used to secure one or more internal components to enclosure. The brackets and supports should be firmly attached to the enclosures in order to adequately secure the internal components to the enclosures. If an enclosure is made of stainless steel, typically the brackets and supports are welded onto internal surfaces of the enclosure. In some cases, the brackets and supports are fastened to the enclosure using fasteners such as screws. In some applications, it may be desirable to form enclosures out of aluminum since aluminum is lightweight and can be anodized to form a colored finish. However, processes for producing stainless steel enclosures may not be directly transferable to producing aluminum enclosures. For example, it can be difficult to weld metal features onto aluminum. In many cases, the strength of a weld onto aluminum is not sufficient to adequately bond the metal features onto the aluminum enclosure and to secure an internal component to the enclosure. In addition, the welding process can produce unsightly welding marks that are visible on the exterior portion of the enclosure.

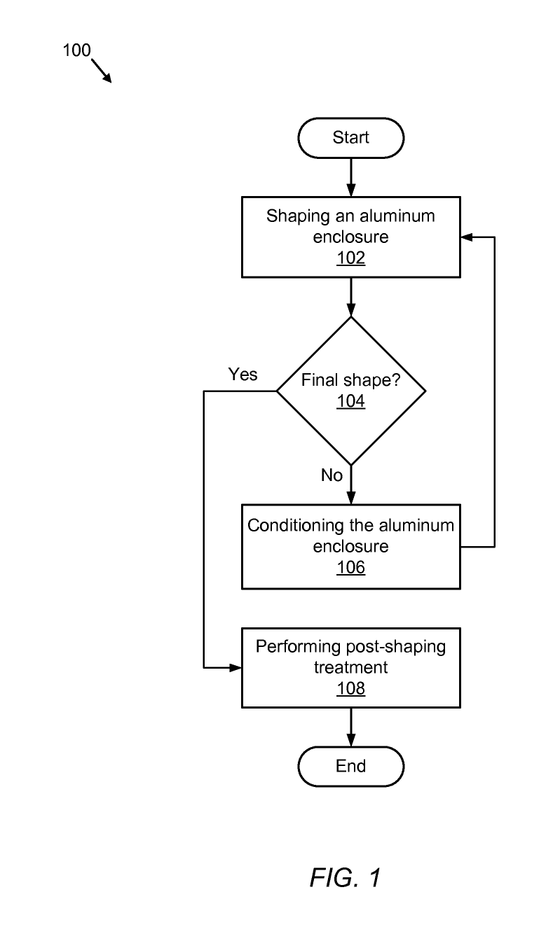

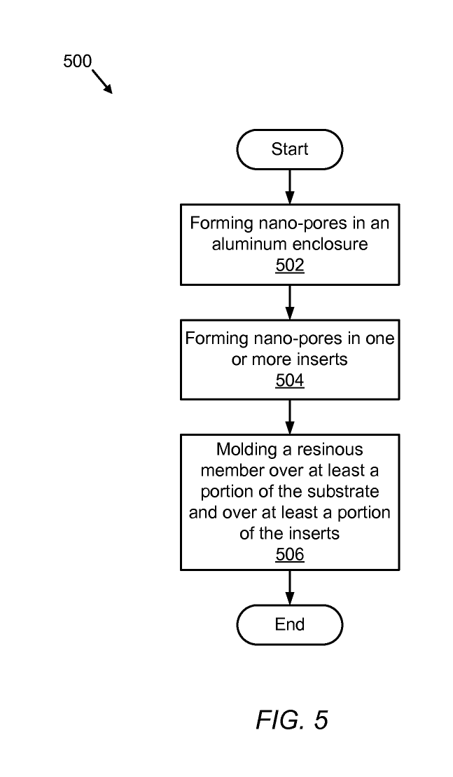

Methods described herein can be used to provide aluminum enclosures having features that can be used to secure internal components to the enclosure. In some embodiments, the methods involve shaping integral features into an aluminum enclosure using forging or other shaping techniques. These embodiments are described below with reference to FIGS. 1-4. In other embodiments, the methods involve molding resinous or plastic features onto the aluminum enclosures. These embodiments are described below with reference to FIGS. 5-7.

FIG. 1 shows flowchart 100, which indicates process steps for forming an aluminum enclosure with integrally formed features. At 102, a shaping operation is performed on the aluminum enclosure. In some embodiments, a first shaping process is used to form a general shape of the enclosure. A general shape can include a back portion that cooperates with side walls to create a cavity. The back portion can have an interior surface corresponding to interior portions of the enclosure and an exterior surface corresponding to the exterior portions of the enclosure. The cavity can have a size and shape suitable for housing at least one internal component of an electronic device. Shaping the general shape of the enclosure typically includes one or more of an extrusion, rolling, and stamping process. In a typical extrusion process, heated aluminum is pushed or drawn through a die having a desired cross-section. In some embodiments, the extruded aluminum is also stretched during or shortly after extrusion to form the desired general enclosure shape. In a typical rolling process, aluminum is passed through one or more sets of consecutive rollers that continuously bend the aluminum into the desired general enclosure shape. In a typical stamping process, aluminum is punched or pressed using a machine to form the desired general enclosure shape. In some embodiments, the general shape of the enclosure is formed by a combination of two or more extrusion, rolling, and stamping processes. After forming the general shape of the enclosure, in some embodiments, the aluminum is further shaped using one or more bending, blanking, piercing or sawing processes.

After the shaping, at 104, the current shape of the aluminum enclosure is compared to a final shape. The final shape can include a general shape of an enclosure and can also include integral features integrally formed into the general enclosure shape. In some embodiments, the integral features include protruding and/or recessed portions in internal portions of the enclosure. The one or more brackets or supports can be configured to support at least one fastener to fasten at least one internal component to the enclosure. The integral features can be formed using any suitable method of shaping aluminum. In some embodiments, the integral features are forming using one or more forging processes. Any suitable forging process can be used. In one embodiment, a press forging process is used, wherein a die is placed onto portions of the enclosure and a compressive force is applied to form the features having desired shapes. In some embodiments, the die is heated to reduce the occurrence of the aluminum cracking and to promote surface flow and shaping.

In some embodiments, the final shape of the aluminum enclosure can require more than one shaping operation. For example, a first shaping operation can be performed to form an aluminum enclosure having a first shape. Then, a subsequent shaping operation can be performed to change the shape of the aluminum enclosure to a second shape. In some cases, the first shape can correspond to a general shape of the enclosure, including a back portion with side walls and the second shape can include the integral features formed into the general shape. In some embodiments, forming the first shape can include different types of shaping operations than forming the second and subsequent shapes. For example, the first shape can be formed using one or more of an extrusion, rolling, stamping, and bending process and the second shape can be formed using one or more of a forging and cutting process. More than one shaping processes may be necessary to form integral features into the housing. For example, the final shape can have protruding integral features that protrude a distance d from the interior surface. In some cases, more than one press forging process may be necessary to form integral features that protrude a distance d from the interior surface. Similarly, more than one press forging process may be necessary to form a desire amount of recess within the enclosure.

Returning to flowchart 100, if the final shape has been attained, a post-shaping treatment 108 can be performed. If the final shape has not been attained, the aluminum enclosure can undergo a conditioning process 106. The conditioning process conditions and prepares the aluminum enclosure for an additional shaping process 102. In this way, shaping 102 and conditioning 106 processes are repeated until a final shape of the aluminum enclosure is attained. The conditioning process can include a softening operation where the aluminum is made more compliant. In some embodiment the softening operation is an annealing process, which generally involves heating the aluminum to a temperature and for a time period sufficient to soften at least a portion of the aluminum. During the forming process of 102, the aluminum material is worked, which can cause adjoining crystals within the aluminum to slip against each other along slip planes. As the aluminum is worked, the resistance to movement along the slip planes can increase and the aluminum can become work hardened. Over working the aluminum can cause the aluminum to crack or break. By using a softening process such as annealing, the microstructure of the aluminum can be restored to a crystalline state, thereby altering the aluminum into a more resilient and workable state. In some cases, it can be beneficial to monitor the mechanical properties or temper rating of the aluminum prior to forging. In one embodiment, for example, it is found that forging an aluminum alloy having a T6 temper rating can cause breaking or cracking of the aluminum. Therefore, if the aluminum is found to have a T6 temper or higher, an annealing process can be used to soften the aluminum to a temper rating of T5 or less prior to a subsequent shaping process. The annealing can occur, for example, in an air furnace. The temperature and time can vary depending upon the type of aluminum or aluminum alloy used. In some embodiments, the aluminum is heated to a temperature of about 415 C+/−30 C for between about 30 minutes to 2 hours. In some cases the rate of cooling is controlled after the heating to achieve an optimal amount of softening.

After the aluminum is conditioned, at 102 an additional shaping procedure can be performed. Generally, it is advantageous to change the shape of the enclosure incrementally with conditioning operations 106 between each of the shaping operations. For example, incremental forging can be used to prevent the aluminum from becoming overworked and crack or break as described above. In addition, the incremental forging can reduce the occurrence of forging related defects that can be formed on the interior and/or exterior surfaces of the aluminum enclosure. The incremental forging can involve slightly modifying the shape of the one or more integral features with each forging until integral features having a final shape is formed. For example, the shapes of the integral features can become slightly more defined with each forging process until a final shape having integral features with well-defined edges and protrude or recess a final distance d from a surface of the enclosure.

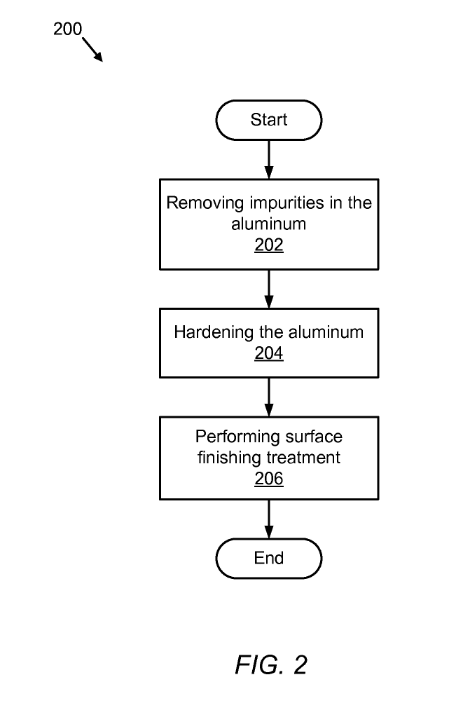

Returning to flowchart 100, after a final shape of the enclosure is attained, the aluminum enclosure can undergo a post-shaping treatment 108. FIG. 2 shows flowchart 200, which indicates process steps for a series of post-shaping treatments 202, 204 and 206 that can be used in accordance with some embodiments. Note that in other embodiments, only one or two of post-shaping treatments 202, 204 and 206 can be used. At 202, impurities that may exist in the aluminum are removed. The impurities can include other metals such as iron, copper, chromium and silver and other materials such as silicon. Often, the impurities are materials that are typically found in small percentages in aluminum alloys. If a surface of the aluminum having these impurities is finished using a polishing or anodizing, the resultant aluminum surface can have a pitted appearance. This can be problematic if a smooth and polished surface is desired. By removing these impurities after the shape of the enclosure is formed and prior to a polishing or anodizing process, the resultant aluminum enclosure can have a smoother and more cosmetically appealing surface. In some embodiments, nearly all the impurities are removed from a surface of the aluminum to leave a substantially pure aluminum surface. It should be noted that in some embodiments it is desirable to remove impurities even if a subsequent polishing or anodizing procedure is not performed. Removal of impurities can be done using, for example, solution heat treatment techniques. Solution heat treatment can include placing the aluminum enclosure in an aqueous solution at elevated temperatures to allow the impurities to dissolve in the aqueous solution. In some embodiments, the solution heat treatment involves heating the aluminum enclosure to temperatures of about 53° C.+/−30 C in the aqueous solution for about 1.5 to 2.5 hours.

After the impurities have been removed, at 204 the aluminum is hardened using an aging process or age hardening process. The aging process can involve heating the aluminum to reorder the microstructure of the aluminum and allow the aluminum to settle to a more hardened state. The process parameters of the aging process can be tuned to provide a microstructure having a small average grain size. In general, an aluminum microstructure having a small grain size can have high yield strength and also a visibly uniform surface. In one embodiment, the aluminum is hardened until a tensile and/or yield strength corresponding to aluminum alloy 6063-T6 temper is achieved. Aluminum alloy 6063-T6 temper typically has a tensile strength of about 30,000 psi (196 MPa) and a yield strength of about 25,000 psi (165 MPa). In some embodiments, the process parameters are tuned to provide an average grain size less than about 100 nm in diameter. This is because, in general, the smaller grain sizes are associated with a more visibly uniform appearance. In one embodiment, the process parameters were tuned to provide an average grain size between about 10 nm and 100 nm in diameter. Typically, the aging process involves heating and holding the aluminum to a prescribed temperature for a considerable period of time. In some embodiments, the aging process involves heating the aluminum to temperatures of between about 15° C. and 375 C for between about 8 to 12 hours.

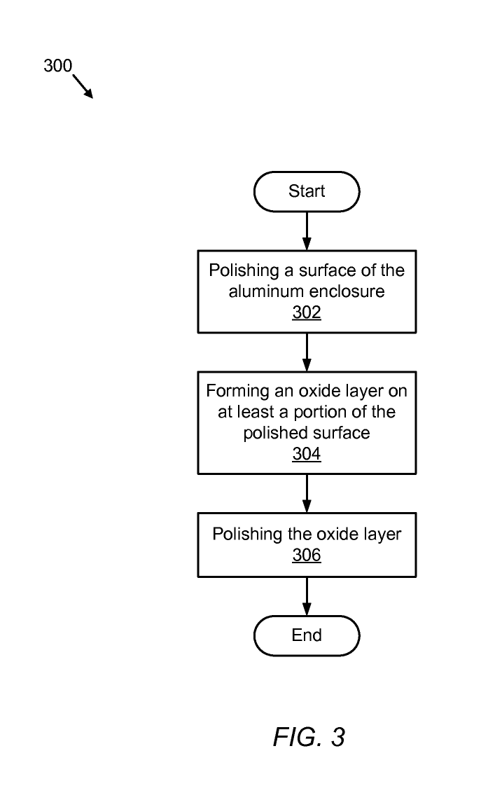

At 206, the aluminum enclosure can undergo a surface finishing treatment. FIG. 3 shows flowchart 300, which indicates process steps for a surface finishing process in accordance with some embodiments. Note that flowchart 300 shows a series of surface finishing procedures, 302, 304 and 306. In some embodiments, all three procedures 302, 304 and 306 are performed while in other embodiments, only one or two of procedures of 302, 304 and 306 are performed. In some embodiments, exterior surfaces are finished while interior surfaces of the enclosure are left unfinished. However, it should be pointed out that the shaping and post-shaping treatment processes of flowcharts 100 and 200 can impact the quality of aluminum enclosure as a whole, including exterior surfaces. At 302, a surface of the aluminum enclosure is polished. The polishing can include a mechanical or chemical polishing or a combination of the two. At 304, the polished surface is anodized to form an aluminum oxide layer, sometimes referred to as simply an oxide layer, on at least a portion of the polished aluminum surface. For example, the oxide layer can be formed on an external surface of the back portion of an enclosure. At 306, the oxide layer can optionally be polished. In some cases, the oxide layer can be dyed to have a color. Since oxide layers are generally porous in nature, they can be readily dyed to impart a lasting colored surface to the aluminum enclosure. At the end of the surface treatment of flowchart 300, the resultant aluminum enclosure can have a uniform, shiny and cosmetically appealing surface quality.

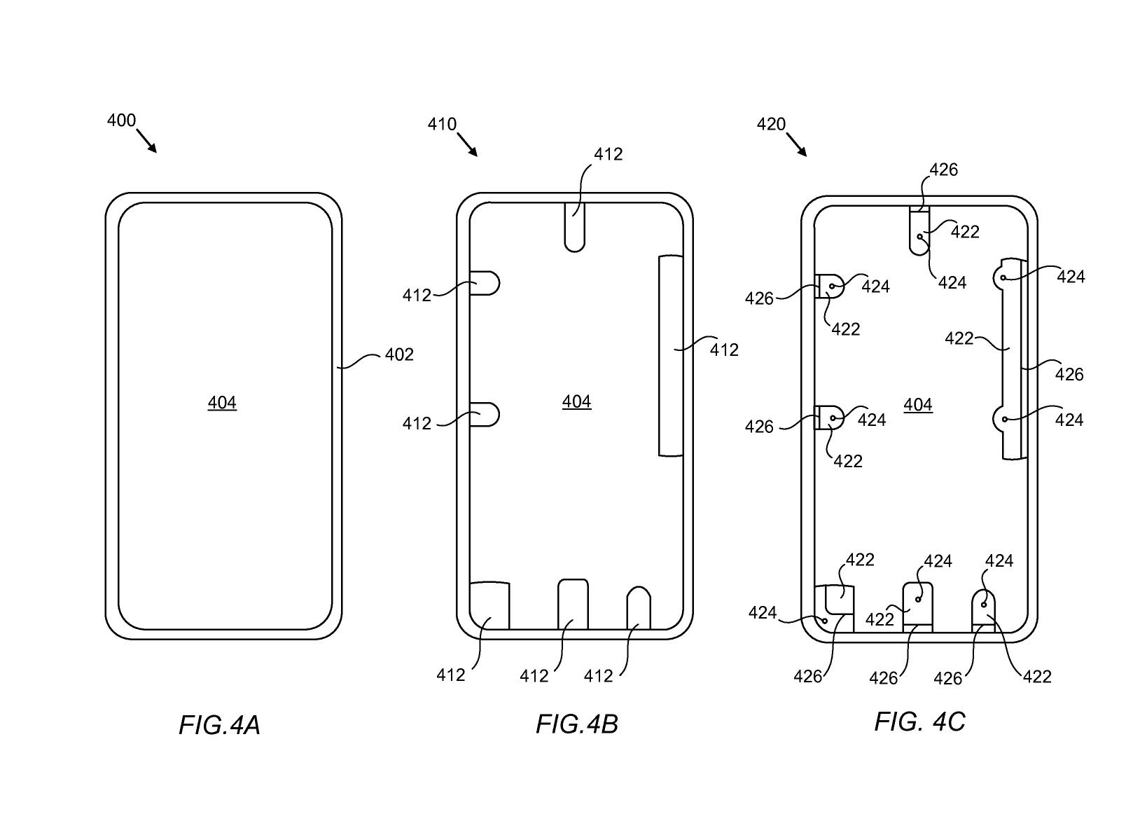

FIGS. 4A-4C illustrate internal views of an aluminum enclosure at various stages of formation in accordance with described embodiments. In some embodiments, the aluminum enclosure is used to house internal components of an electronic device, such as a portable media player or phone. The back side (not shown) of the aluminum enclosure of FIGS. 4A-4C can include an exterior surface of the enclosure. In some embodiments, it is desirable to form an exterior surface that is cosmetically appealing. Thus, in these embodiments, forming the internal features within the aluminum enclosure should not detrimentally affect the exterior surface of the aluminum enclosure. For example, in these embodiments, processes for forming the internal features should not deform the exterior surface and should provide an exterior surface having small average aluminum grain size.

At FIG. 4A, the aluminum enclosure has been formed to have a first shape 400. As described above with reference to flowchart 100, the first shape 400 can correspond to the general shape of the enclosure, in this case, an enclosure for an electronic device. In some embodiments, an aluminum piece is subjected to one or more of an extrusion, rolling, stamping and bending processes to form to the first shape 400. As shown, first shape 400 is a substantially rectangular shaped frame having upward bended sides 402 that form an interior portion 404. Interior portion 404 can be configured to house internal components of the electronic device. After first shape 400 is formed, the aluminum enclosure can be subjected to an annealing process in preparation for a subsequent forming process. As described above with reference to conditioning process 106, an annealing process can involve heating the aluminum to soften the aluminum to a workable state such that the aluminum material will not break or crack during the subsequent shaping process.

At FIG. 4B, the aluminum enclosure has been processed to form a second shape 410, which includes protruding features 412. Protruding features 412 protrude a distance d1 from the surface of interior portion 404. As described above with reference to process step 106, protruding features 412 can be formed using a forging process. The forging process can include placing a die having recessed features corresponding to protruding features 412 in interior portion 404 and applying a compressive force sufficient to create protruding features 412. In some embodiments, the exterior surface of the housing is protected in order to maintain a shape of the exterior surface of the housing. For example, the exterior surface can be placed in a die, mold or fixture having a flat surface. After protruding features 412 are formed, the aluminum enclosure can be subjected to a second annealing process in soften the aluminum for a subsequent second forming process.

At FIG. 4C, the aluminum enclosure has been processed to form a third shape 420, which includes protruding features 422. Protruding features 422 have similar shapes to protruding features 412 but have more refined edges. In some embodiments, protruding features 422 protrude from the surface of interior portion 404 a distance d, which is greater than distance d1. Protruding features 422 additionally have dimples 424 and bended features 426. Dimples 424 can be used, for example as centering marks for a subsequent machining operation. For example, holes can be formed at the locations of dimples 424 during a subsequent machining process to accommodate fasteners such as screws used to fasten internal components to the enclosure. Bended features 426 can be used, for example, to accommodate dimensions of internal components of the electronic device. Protruding features 422 can be formed by placing a second die having recessed features corresponding to protruding features 422 in interior portion 404 and applying a second compressive force sufficient to change the shape of protruding features 412 to the shape of protruding features 422. The exterior surface can be placed in a die, mold or fixture having a flat surface to maintain a shape of the exterior surface. After the aluminum enclosure has been forged to have shape 420, the aluminum enclosure can undergo yet another annealing process and another forging process to further transform the shapes of protruding features 422. The annealing process following by forging process can continue until the aluminum enclosure has a final desired shape. By incrementally changing the shape of the aluminum enclosure using multiple annealing and forming procedures, stress on the aluminum, which can lead to cracking or breaking, can be reduced. After the aluminum enclosure has a desired final shape, a microstructure treatment process, such as described above with reference to flowchart 200 of FIG. 2, and/or a surface finishing process, such as described above with reference to flowchart 300 of FIG. 3, can be performed.

Turning now to FIGS. 5-7, in alternative embodiments, resinous or plastic features are formed in aluminum enclosures. The plastic features can be, for example, brackets or supports within internal portions of the aluminum enclosures to support internal components. FIG. 5 shows flowchart 500, which indicates process steps for forming an aluminum enclosure with plastic or resinous features. It should be noted that prior to flowchart 500, the shape of the aluminum enclosure can be formed using any suitable technique, including extrusion, rolling and stamping. In some cases, the shape of the aluminum enclosure is formed by machining a single billet of aluminum. At 502, nano-pores are formed in an aluminum enclosure. The nano-pores are formed in at least the portion of the housing that the plastic features will be formed onto. The nano-pores can be used to enhance the bonding of the aluminum to the resinous material that is formed in subsequent process 506. The nano-pores are elongated voids that formed in a substantially perpendicular direction in relation to the surface of the aluminum. In some embodiments, the nano-pores are formed by exposing a surface of the aluminum enclosure to an oxidative treatment. In one embodiment, the oxidative treatment includes exposing the aluminum surface to an electrolytic bath comprising an oxidizing agent such as phosphoric acid or sodium hydroxide and applying a current to the electrolytic bath. The resultant aluminum surface can have nano-pores having an average diameter of between about 40 and 100 nanometers.

At 504, nano-pores are formed in one or more inserts. In some embodiments, the inserts are fastening features used to fasten one or more internal components to the aluminum enclosure. In one embodiment, the inserts are threaded metal pieces, such as threaded nuts, that can couple with corresponding threaded screws used to fasten the one or more internal components to the enclosure. In some embodiments the inserts are made of aluminum so that they are compatible with a subsequent anodizing procedure. This is because stainless steel and other metals can contaminate an aluminum anodizing bath. The nano-pores can be formed on at least exterior surfaces of the inserts to enhance the bonding of the metal inserts to the resinous material formed in subsequent process 506. In some embodiments, the nano-pores are formed by exposing at least the exterior surfaces of the inserts to an oxidative treatment. In one embodiment, the nano-pores are formed by exposing the exterior surfaces to an electrolytic bath comprising an oxidizing agent such as phosphoric acid or sodium hydroxide. In some embodiments, portions of the one or more inserts are masked or plugged to prevent exposure of these portions to the oxidative treatment. For example, threaded portions of nut inserts can be plugged to prevent exposure of the threads from exposure to the oxidative treatment. In this way, nano-pores can be prevented from forming on threaded portions of the inserts to maintain their structural integrity.

At 506, a plastic or resinous member is molded over at least a portion of the aluminum enclosure and over at least a portion of the one or more inserts. This can be done using an insert molding process where resinous material in liquid form is injected into a mold. After the liquid resinous material is allowed to harden, the hardened resinous material can retain a corresponding shape of the mold. In the present application, the liquid resinous material can be molded over surfaces that have been treated to have nano-pores, which includes surfaces of the aluminum enclosure and inserts. As the liquid resinous material is molded over the treated surfaces, the liquid resinous material can flow within the elongated voids of the nano-pores. Once the resinous material hardens, part of the hardened resinous material remains within the voids and can act as an anchor that enhances the bonding of the resinous material to aluminum enclosure and inserts. Note that since both the aluminum enclosure and the inserts have been pre-treated to form nano-pores, the resinous material is anchored to both. After the resinous material is molded over the aluminum enclosure and the one or more inserts, the one or more inserts can be used to fasten an internal component to the resinous member. For example, if the inserts are threaded nuts, corresponding screws can be used to fasten the internal components to the resinous member and the aluminum enclosure.

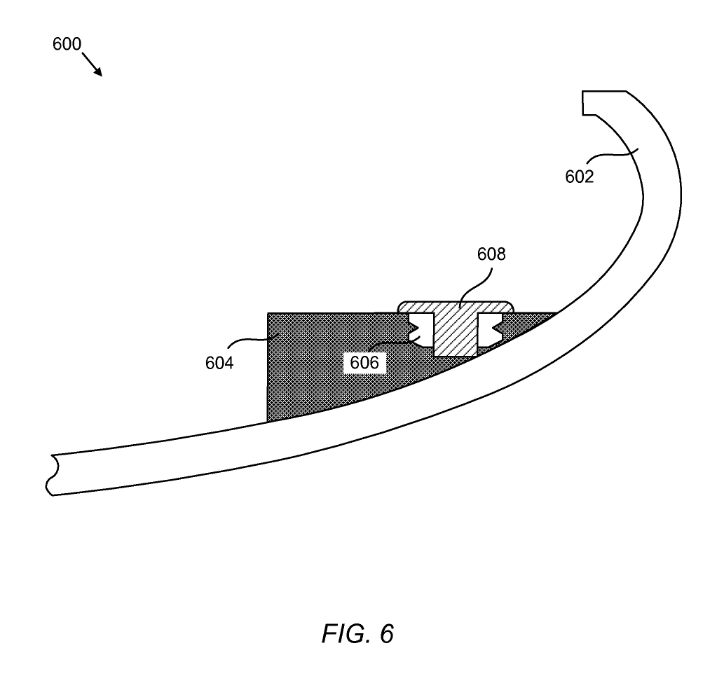

FIG. 6 illustrates a cross-section view 600 of a portion of an aluminum enclosure with a plastic feature in accordance with described embodiments. Aluminum enclosure 602 has a shape configured to house internal components within. Resinous member 604 is molded onto an internal surface of aluminum enclosure 602 and onto an exterior surface of insert 606. Resinous member 604 and insert 606 together can form an internal feature, such as a bracket or support configured to support one or more internal components to the aluminum enclosure 602. Insert 606 can have an exterior resin engaging surface and an interior fastener engaging surface. In the embodiment shown, fastener 608 is coupled to insert 606. In some embodiments, insert 606 is a threaded nut and fastener 608 is a corresponding threaded screw. In some cases, an internal component (not shown) can be fastened to resinous member 604 using fastener 608 and insert 606. The internal component can be, for example, an electronic component such as a printed circuit board (PCB) or a battery assembly. During assembly, in some embodiments, at least a portion of an interior surface of aluminum enclosure 602 and at least a portion of an external surface of insert 606 are pre-treated to have nano-pores, as described above, to enhance bonding of resinous member 604 to aluminum enclosure 602 and insert 606. After insert 606 is molded within resinous member 604, fastener 608 can be used to fasten one or more internal components to aluminum enclosure 602. In this way, insert 606 and resinous member 604 can cooperate together to secure the one or more components to the aluminum enclosure 602.

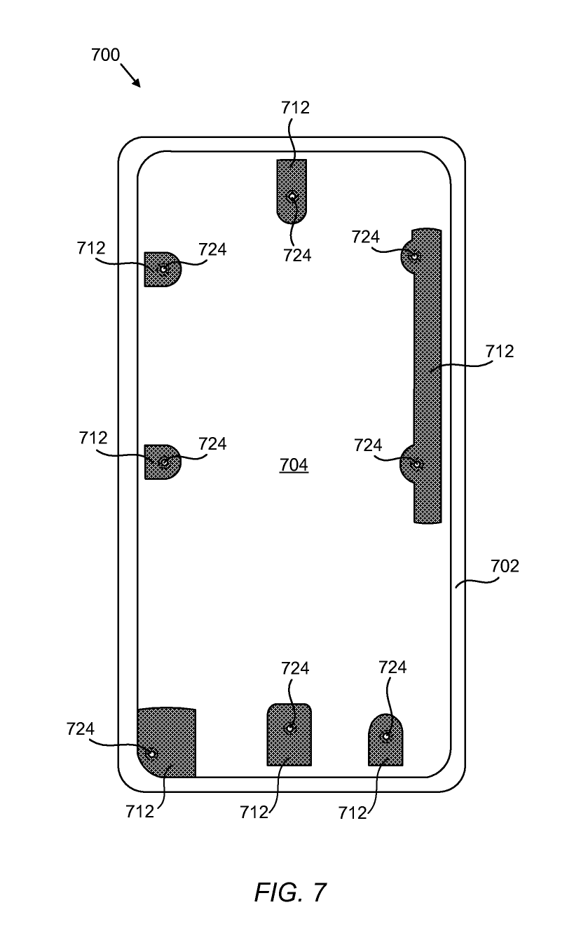

FIG. 7 illustrates an internal view of an aluminum enclosure assembly 700 with plastic features formed in accordance with described embodiments. Aluminum enclosure 702 is shaped to enclose internal components as part of an electronic device. Aluminum enclosure 702 can be formed using any suitable technique, including extrusion, rolling and stamping. In some embodiments, the shape of the aluminum enclosure 702 is formed by machining a single billet of aluminum. Plastic or resinous features 712 are formed over interior surface 704 of aluminum enclosure 702. Interior surface 704 can include interior side walls of aluminum enclosure 702. Molded within resinous features 712 are inserts 712. In the embodiment shown, inserts 724 are threaded nuts that are configured to engage with corresponding screws (not shown). In this way, inserts 724 and their corresponding screws can be used to fasten one or more internal components to resinous features 712 and thereby, to aluminum enclosure 702. During assembly of aluminum enclosure assembly 700, surfaces of aluminum enclosure 702 and inserts 724 can be pre-treated to have nano-pores to enhance bonding of resinous features 712 during an insert molding process. In some embodiments, aluminum enclosure 702 and inserts 724 are immersed in an oxidative electrolytic bath to form nano-pores in substantially all exposed surfaces of aluminum enclosure 702 and inserts 724. In other embodiments, portions of the surface of aluminum enclosure 702 and/or inserts 724 are masked off to prevent exposure to the oxidative electrolytic bath. For example, in some cases it can be beneficial to mask off the exterior surfaces of the enclosure 702 or threaded openings of inserts 724 so that nano-pores are not formed on these surfaces.

In some embodiments, aluminum enclosure assembly 700 undergoes a subsequent anodizing process to form an oxide layer on exposed surfaces of aluminum. During the anodizing process, aluminum enclosure assembly 700 can be immersed in an anodizing bath. As described above, stainless steel can contaminate and ruin an anodizing process. Therefore, in some embodiments, inserts 724 are made of a material that is compatible with an anodizing bath solution, such as aluminum. In alternative embodiments, inserts 724 can be masked prior to exposure to the anodizing bath to prevent contamination.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A method for forming an aluminum enclosure for an electronic device, the method comprising:
(a) performing a shaping operation on the aluminum enclosure;
(b) comparing a current shape of the aluminum enclosure to a final shape of the aluminum enclosure;
(c) performing a conditioning operation on the aluminum enclosure if, based on the comparison, the current shape is not the final shape;
(d) repeating (a), (b) and (c) until the current shape is the final shape; and
(e) performing a post-shaping operation on the aluminum enclosure.

2. The method of claim 1, wherein the conditioning operation comprises softening at least a portion of the aluminum enclosure using an annealing process, wherein the annealing process alters the microstructure of at least a portion of the aluminum enclosure into a resilient state that is resistant to cracking during a subsequent shaping process.

3. The method of claim 1, wherein the post-shaping operation comprises hardening the aluminum enclosure using an aging process, wherein the aging process comprises heating the aluminum enclosure until a predetermined yield strength is obtained.

4. The method of claim 3, wherein the aging process comprises heating the aluminum enclosure to between about 150 C and 375 C for between about 8 to 12 hours.

5. The method of claim 3, wherein the aging process comprises heating the aluminum enclosure until an average grain size of less than about 100 nm is achieved.

6. The method of claim 1, wherein the post-shaping operation comprises an impurities removal operation.

7. The method of claim 6, wherein the impurities removal operation comprises heating the aluminum enclosure in an aqueous solution until impurities dissolve in the aqueous solution.

8. The method of claim 1, wherein performing the shaping operation includes forming a general shape of the aluminum enclosure using a process selected from the group consisting of extrusion, rolling, stamping and bending.

9. The method of claim 1, wherein performing the shaping operation includes forming at least one integral feature configured to support at least one fastener used to fasten at least one internal component to the aluminum enclosure.

10. The method of claim 9, wherein forming the at least one integral feature includes a press forging process, wherein the press forging process comprises placing a die on a surface of the aluminum enclosure and applying a compressive force thereon.

11. The method of claim 10, wherein a plurality of press forging process and a plurality of conditioning operations are performed to form the final shape, wherein each press forging process is preceded with a conditioning process.

12. The method of claim 1, wherein the final shape includes a back portion with integrally formed side walls that cooperate to create a cavity having a shape and size suitable for housing at least one internal component of the consumer electronic device.

13. A method for forming an aluminum enclosure for an electronic device, the method comprising:
shaping the aluminum enclosure into a first shape having a back portion integrally formed with side walls, the back portion having an interior surface and an exterior surface, where the back portion and the side walls create a cavity having a shape and size suitable for housing at least one internal component;
conditioning the aluminum enclosure such that at least a portion of the aluminum enclosure is softened to prevent cracking during a subsequent shaping process;
shaping the aluminum enclosure into a second shape having at least one integral feature integrally formed in the back portion and extending a distance from the interior surface, wherein the at least one integral feature is configured to support at least one fastener used to fasten the at least one internal component within the cavity of the aluminum enclosure.

14. The method of claim 13, wherein conditioning the aluminum enclosure comprises an annealing process comprising altering the microstructure of at least a portion of the aluminum enclosure into a resilient state that is resistant to cracking during a subsequent shaping process.

15. The method of claim 13, wherein shaping the aluminum into the second shape comprises a press forging process comprising placing a die on a surface of the aluminum enclosure and applying a compressive force thereon.

16. The method of claim 15, wherein shaping the aluminum into the second shape comprises a plurality of press forging processes with each of the press forging processes preceded by a conditioning process, wherein after the plurality of press forging processes is complete the integral features protrude a distance d from the interior surface.

17. The method of claim 13, further comprising:
removing impurities from the aluminum enclosure by immersing the aluminum enclosure in a heated solution.

18. The method of claim 17, wherein the impurities include at least one of iron, silicon, copper, chromium and silver.

19. The method of claim 13, further comprising:
hardening the aluminum enclosure by heating the aluminum enclosure until a yield strength of about 25,000 psi is achieved.

20. The method of claim 19, wherein after the hardening, the aluminum enclosure has an average grain size of less than about 100 nm in diameter.

21. The method of claim 13, further comprising:
forming an oxide layer on at least the external surface of the back portion using an anodizing process.

22. An aluminum enclosure for an electronic device, the aluminum enclosure comprising:
an interior surface comprising a first group of nano-pores; and
at least one bracket secured to the interior surface and configured to support at least one component to the aluminum enclosure, the at least one bracket comprising:
an aluminum insert having an external surface comprising a second group of nano-pores, and
a resinous member having a first securing portion and a second securing portion, the first securing portion molded within at least a portion of the interior surface comprising the first group of nano-pores and the second securing portion molded within at least a portion of the external surface comprising the second group of nano-pores.

23. The aluminum enclosure of claim 22, wherein the aluminum insert further comprises a fastening surface configured to accept a fastener for fastening the at least one component to the interior surface.

24. The aluminum enclosure of claim 23, wherein the fastening surface is threaded and configured to engage with a correspondingly threaded fastener.

25. The aluminum enclosure of claim 22, wherein the at least one bracket protrudes a distance above the internal surface.

26. The aluminum enclosure of claim 22, wherein the at least one bracket comprises a plurality of aluminum inserts, each aluminum insert having an external surface comprising nano-pores.

27. The aluminum enclosure of claim 26, wherein the resinous member comprising a plurality of second securing portions, each second securing portion molded within at least a portion of the nano-pores of each of the plurality of aluminum inserts.

28. The aluminum enclosure of claim 22, wherein the aluminum insert and the resinous member cooperate together to secure the at least one component to the interior surface of the aluminum enclosure.

29. A method of forming a bracket for an aluminum enclosure, the method comprising:
creating a first group of nano-pores in an interior surface of an aluminum enclosure;
creating a second group of nano-pores in an exterior surface of an aluminum insert; and
forming a supportive bracket on the interior surface of the aluminum enclosure, the forming comprising:
molding a first securing portion of a resinous member within at least a portion of the interior surface comprising the first group of nano-pores, and
molding a second securing portion of the resinous member within at least a portion of the external surface comprising the second group of nano-pores.

30. The method of claim 27, wherein the aluminum insert comprises a fastening surface configured to engage with a fastener for fastening at least one component to the interior surface.

31. The method of claim 27, further comprising creating nano-pores in exterior surfaces of a plurality of aluminum inserts.

32. The method of claim 31, wherein forming the supportive bracket comprises molding a plurality of second securing portions within at least a portion of nano-pores of the plurality of aluminum inserts.

33. The method of claim 29, wherein creating the first group of nano-pores and the second group of nano-pores comprises exposing the interior surface and the external surface to an oxidative treatment.
